(19) United States
(12) Patent Application Publication
(10) Pub. No.: US 2026/0198008 A1
(43) Pub. Date: Jul. 9, 2026

(54) SEMICONDUCTOR DEVICE, ELECTRONIC APPARATUS INCLUDING THE SAME, AND METHOD OF MANUFACTURING SEMICONDUCTOR DEVICE

(71) Applicant: Samsung Electronics Co., Ltd., Suwon-si (KR)

(72) Inventors: Sijung YOO, Suwon-si (KR); Dukhyun CHOE, Suwon-si (KR); Seunggeol NAM, Suwon-si (KR)

(73) Assignee: Samsung Electronics Co., Ltd., Suwon-si (KR)

(21) Appl. No.: 19/244,860

(22) Filed: Jun. 20, 2025

(30) Foreign Application Priority Data
Jan. 7, 2025 (KR) 10-2025-0002387

(51) Int. Cl. H10B 43/27; H10B 43/10; H10B 43/35; H10B 51/20; H10B 51/30; H10D 30/01; H10D 30/69; H10D 64/01; H10D 64/66; H10D 64/68

(52) U.S. Cl. CPC H10B 43/27; H10B 43/10; H10B 43/35; H10B 51/20; H10B 51/30; H10D 30/0413; H10D 30/0415; H10D 30/693; H10D 30/701; H10D 64/033; H10D 64/037; H10D 64/675; H10D 64/689

(57) ABSTRACT

Provided are a semiconductor device, an electronic apparatus including the semiconductor device, and a method of manufacturing the semiconductor device. The method of manufacturing the semiconductor device includes alternately stacking a spacer layer and a mold layer, forming a channel hole to penetrate the spacer layer and the mold layer, forming a gate stack inside the channel hole, removing the mold layer, after the forming a gate electrode, forming a gate electrode in a space.

### CROSS-REFERENCE TO RELATED APPLICATION

This application is based on and claims priority under 35 U.S.C. Korean Patent Application No. 10-2025-0002387, filed on Jan. 7, 2025, in the Korean Intellectual Property Office, the disclosure of which is incorporated by reference herein in its entirety.

### BACKGROUND

### 1. Field

Some example embodiments relate to semiconductor devices of which a channel layer has improved thermal stability, electronic apparatuses including the same, and methods of manufacturing the semiconductor device.

### 2. Description of the Related Art

As hard disks are replaced by solid state drives (SSDs), NAND flash memory devices, which are non-volatile memory devices, are being widely used. As nonvolatile memory devices become smaller and more highly integrated, vertical NAND flash memory devices in which a plurality of memory cells are stacked in a direction perpendicular to the substrate are being developed.

Recently, as higher integration and/or lower power are desired, interest in improving issues such as a relatively high program/erase voltage, a relatively small memory window, and/or a relatively short data retention. In nonvolatile memory devices, charge transfer between memory cells may occur due to an increase in the number of stacked memory cells and a decrease in height of the stacked memory cells, and such charge transfer may deteriorate charge retention of the memory cells. The performance of nonvolatile memory devices is improved by using a channel including oxide semiconductors having better electrical properties compared to polycrystalline silicon.

### SUMMARY

Some example embodiments provide semiconductor devices in which thermal stability of a channel layer is improved.

Some example embodiments provide electronic apparatuses including a semiconductor device having improved thermal stability.

Some example embodiments provide methods of manufacturing a semiconductor device having improved thermal stability.

Additional aspects will be set forth in part in the description which follows and, in part, will be apparent from the description, or may be learned by practice of the presented example embodiments of the disclosure.

According to an example embodiment of the disclosure, a method of manufacturing a semiconductor device includes alternately stacking a spacer layer and a mold layer, etching the spacer layer and the mold layer to form a channel hole penetrating therethrough, forming a gate stack inside the channel hole, removing the mold layer, forming a gate electrode in a space where the mold layer has been removed, and after the forming the gate electrode, forming a channel layer including an oxide semiconductor on the gate stack.

The method of manufacturing the semiconductor device may further include forming a sacrificial layer on the gate stack after the forming the gate stack and before the removing the mold layer.

The method of manufacturing the semiconductor device may further include removing the sacrificial layer after the removing the mold layer.

The forming the gate stack may include depositing a ferroelectric precursor and heat-treating the ferroelectric precursor.

The heat-treating may be performed in a range of about 400° C. to about 1,000° C.

The sacrificial layer may include silicon oxide, silicon nitride, aluminum oxide, or aluminum nitride.

The sacrificial layer may include at least one of TiN, W, Mo, Ru, Pt, or Y.

The gate stack may include at least one layer, and an interface area of the at least one layer includes at least one of TiN, W, Mo, Ru, Pt, or Y after the sacrificial layer is removed.

The gate stack may include a channel blocking layer, a charge trap layer, and a charge tunneling layer sequentially provided on an inner side of the channel hole, and an interface area of the charge tunneling layer or the charge trap layer includes at least one of TiN, W, Mo, Ru, Pt, or Y.

The gate stack may include a ferroelectric layer, and the ferroelectric layer may include at least one of TiN, W, Mo, Ru, Pt, or Y at an interface area thereof with the channel layer.

The gate stack may include a silicon oxide layer, a ferroelectric layer, and a high permittivity layer stacked sequentially on an inner side of the channel hole, and at least one of TiN, W, Mo, Ru, Pt, or Y may be included at an interface area thereof with the channel layer.

The mold layer may include silicon nitride.

According to an example embodiment of the disclosure, a semiconductor device includes a gate electrode and a spacer layer alternating on each other, a stack structure of the gate electrode and the spacer layer including a channel hole penetrating therethrough, a channel hole penetrating the gate electrode and the spacer layer, a gate stack on an inner side of the channel hole, and a channel layer on the gate stack and including an oxide semiconductor, wherein the gate stack includes at least one layer, and an interface area of the at least one layer includes at least one of TiN, W, Mo, Ru, Pt, or Y at a range of about 0.5 at % to about 2 at %.

According to an example embodiment of the disclosure, an electronic apparatus includes a host, a semiconductor device, and a memory controller configured to control the semiconductor device to perform at least one of reading data from or writing data on the semiconductor device in response to a request of the host, wherein the semiconductor device includes a gate electrode and a spacer layer alternating on each other, a stack structure of the gate electrode and the spacer layer including a channel hole penetrating therethrough, a gate stack on an inner side of the channel hole, and a channel layer on the gate stack and including an oxide semiconductor, and wherein the gate stack includes at least one layer, and an interface area of the at least one layer includes at least one of TiN, W, Mo, Ru, Pt, or Y at a range of about 0.5 at % to about 2 at %.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 schematically illustrates a semiconductor device according to an example embodiment;

FIG. 2 is a cross-sectional view of the semiconductor device taken along line A-A′ of FIG. 1;

FIG. 3 shows an example in which a gate stack of FIG. 2 is changed to a ferroelectric layer;

FIG. 4 shows an example in which the gate stack of FIG. 2 is changed to other layers;

FIGS. 5A to 5I are diagrams for explaining a method of manufacturing a semiconductor device according to an example embodiment;

FIGS. 6A and 6B are diagrams for explaining a method of manufacturing a semiconductor device according to another example embodiment;

FIGS. 7A and 7E are diagrams for explaining a method of manufacturing a semiconductor device according to another example embodiment;

FIGS. 8A to 8D are diagrams for explaining a method of manufacturing a semiconductor device according to another example embodiment;

FIG. 9 shows a result of APT analysis of a semiconductor device according to an example embodiment;

FIG. 10 is a circuit diagram of a vertical semiconductor device according to an example embodiment;

FIG. 11 is a schematic block diagram of a display apparatus including a display driver integrated circuit (DDI) according to an example embodiment;

FIG. 12 is a block diagram of an electronic apparatus according to an example embodiment;

FIG. 13 is a block diagram of an electronic apparatus according to an example embodiment;

FIG. 14 is a conceptual diagram schematically showing a device architecture that may be applied to an electronic apparatus according to an example embodiment; and

FIG. 15 is a conceptual diagram schematically showing a device architecture that may be applied to an electronic apparatus according to another example embodiment.

### DETAILED DESCRIPTION

Reference will now be made in detail to example embodiments, examples of which are illustrated in the accompanying drawings, wherein like reference numerals refer to like elements throughout. In this regard, example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “one of,” “one or more of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

Hereinafter, a semiconductor device, an electronic apparatus including the same, and a method of manufacturing the semiconductor device according to some example embodiments will be described in detail with reference to the accompanying drawings. In the drawings, like reference numerals refer to the like elements, and sizes of elements in the drawings may be exaggerated for clarity and convenience of explanation. Terms such as “the first” and “the second” may be used to explain various elements but the elements should not be limited by terms. The terms are only used to distinguish one element from another.

The singular forms are intended to include the plural forms as well, unless the context clearly indicates otherwise. Also, it should be understood that, when a part “comprises” or “includes” an element in the specification, unless otherwise defined, other elements are not excluded from the part and the part may further include other elements. In addition, the size and thickness of each element may be exaggerated for the clarity of the description. In addition, when a desired (or alternatively, predetermined) material layer is described as being on a substrate or another layer, the material layer may be present on the substrate or another layer while being in direct contact with the substrate or the other layer, or another layer may be present between the material layer and the substrate of the other layer. In addition, since materials included in each layer in the example embodiment below are examples, other materials may be used.

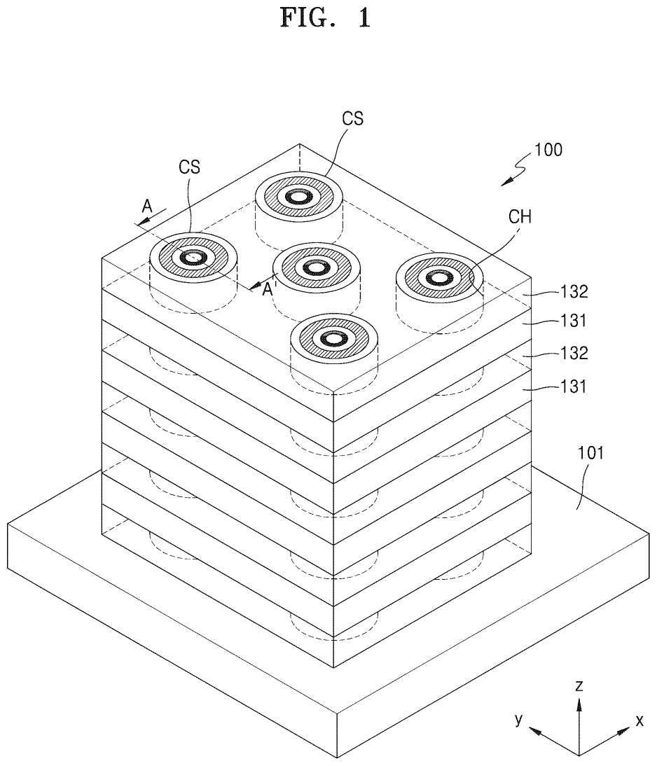

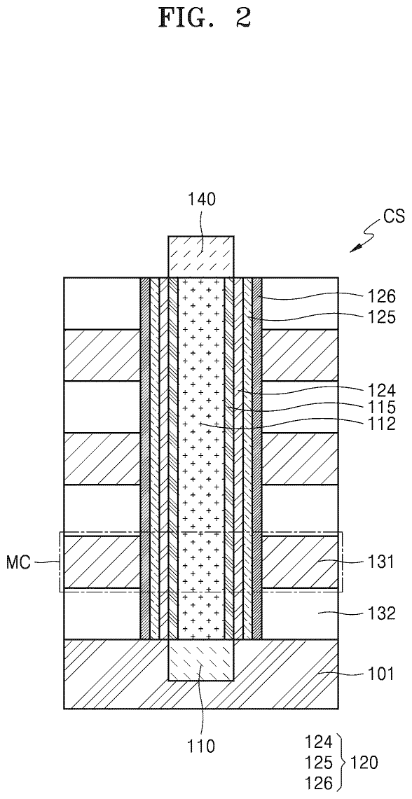

FIG. 1 is a perspective view schematically illustrating a semiconductor device according to an example embodiment, and FIG. 2 is a cross-sectional view taken along line A-A′ of FIG. 1.

Referring to FIG. 1, a semiconductor device 100 includes a plurality of cell strings CS arranged on a substrate 101. Here, each cell string CS may extend in a first direction (a z-axis direction) with respect to the substrate 101. The first direction may be a direction perpendicular to the substrate 101. The plurality of cell strings CS may be arranged in various shapes on the substrate 101. A gate electrode 131 and a spacer layer 132 may be alternately stacked on a substrate 101. A channel hole CH may be provided to penetrate a laminate of the gate electrode 131 and the spacer layer 132 in a first direction (the z-axis direction) perpendicular to the substrate 101.

The channel hole CH may be formed to have, for example, a circular cross-section. However, the cross-sectional shape of the channel hole CH is not limited thereto.

An area of the cell string CS excluding the gate electrode 131 and the spacer layer 132 may have a stacked structure of a plurality of cylindrical shells in the channel hole CH. However, the structure of the cell string CS is not limited thereto and may have other shapes and structures.

Referring to FIG. 2, a gate stack 120 and a channel layer 115 may be provided inside the channel hole CH. The gate stack 120 may include at least one layer. The gate stack 120 may include, for example, a charge tunneling layer 124, a charge trap layer 125, and a charge blocking layer 126. The channel layer 115 may be provided on the charge tunneling layer 124, and a filler 112 may be provided on the channel layer 115.

The cell string CS may include a plurality of memory cells MC stacked in a direction perpendicular to the substrate 101 (the z-axis direction). The memory cell MC may be a basic unit cell for writing and erasing data.

The substrate 101 may include, but is not limited to, a single crystal silicon substrate, a compound semiconductor substrate, or a silicon on insulator SOI substrate. Additionally, the substrate 101 may further include, for example, an impurity-doped region, electronic elements such as transistors, and/or periphery circuits for selecting and controlling memory cells that store data.

The filler 112 may include, for example, silicon oxide, silicon nitride, or air, but is not limited thereto. Each of the channel layer 115, the charge tunneling layer 124, and the charge trap layer 125 may extend in the same direction as the substrate 101 and may be shared by a plurality of memory cells MC.

The channel layer 115 may include an oxide semiconductor. The oxide semiconductor may be an oxide including at least one of indium (In), gallium (Ga), zinc (Zn), tungsten (W), tin (Sn), or hafnium (Hf). The oxide semiconductor may include, for example, zinc indium oxide (ZIO), indium gallium oxide (IGO), or indium gallium zinc oxide (IGZO). The oxide semiconductor may include InGaZnO, ZrInZnO, InGaZnO₄, ZnInO, In₂O₃, HfInZnO, or a combination thereof.

The charge tunneling layer 124 is a layer in which charge tunneling occurs, and may include, for example, silicon oxide or metal oxide, but example embodiments are not limited thereto.

The gate electrodes 131 are stacked apart from each other in a direction perpendicular to the substrate 101, and the spacer layer 132 may be provided between the gate electrodes 131. The spacer layer 132 may include an insulating material and separate the gate electrodes 131 in memory cell MC units such that the gate electrodes 131 may be driven independently. In FIG. 1, the source electrode and the drain electrode are not illustrated, but in FIG. 2, a source electrode 110 and a drain electrode 140 are illustrated. The source electrode 110 may be provided under the channel layer 115, and the drain electrode 140 may be provided on the channel layer 115. However, example embodiments are not limited thereto, and positions of the source electrode 110 and the drain electrode 140 may be changed. The drain electrode 140 may be connected to a bit line.

In FIG. 2, the source electrode 110 is illustrated as being connected to each cell string CS, but the source electrode 110 may also be commonly connected to each cell string CS.

Referring to the overall structure, the channel layer 115 surround a side surface of the filler 112, the charge tunneling layer 124 may surround a side surface of the channel layer 115, and the charge trap layer 125 may surround a side surface of the charge tunneling layer 124. The charge blocking layer 126 may surround the side of the charge trap layer 125.

Each channel corresponding to the gate electrode 131 may be formed in the channel layer 115 between the source electrode 110 and the drain electrode 140. When a desired (or alternatively, predetermined) voltage is applied to the gate electrode 131 in each memory cell MC, charge flowing between the source electrode 110 and the drain electrode 140 in the channel layer 115 corresponding to the gate electrode 131 may pass through the charge tunneling layer 124 and be captured in the charge trap layer 125, thereby allowing information to be stored. The memory cell MC may operate as a single transistor, and information may be programmed by a change in the threshold voltage of the transistor.

The gate electrode 131 may control the corresponding channel layer 115, and a word line may be electrically connected to the gate electrode 131. The gate electrode 131 may include a metal material with relatively good electrical conductivity, conductive oxide, metal nitride, silicon doped with impurities, or a two-dimensional conductive material. The metal material and metal nitride may include, for example, Au, Ti, TiN, TaN, W, Mo, WN, Pt or Ni, or a combination thereof. The conductive oxide may include, for example, indium tin oxide (ITO), indium zinc oxide (IZO), etc. However, this is merely an example and the gate electrode 131 may include various other materials. The spacer layer 132 may serve as insulation and a separation between the gate electrodes 131. The spacer layer 132 may include, for example, silicon oxide, silicon nitride, a metal organic framework, or boron nitride. The metal organic framework may include porous solid materials synthesized through self-assembly based on metal nodes and organic ligands. The metal organic framework may include, for example, UiO-66 or ZIF-8. Boron nitride may include amorphous boron nitride (BN) or amorphous boron carbon nitride (BCN).

The charge blocking layer 126 may act as a barrier to block charge movement between the charge trap layer 125 and the gate electrode 131. One side of the charge blocking layer 126 may be in contact with the charge trap layer 125, and the other side of the charge blocking layer 126 may be in contact with the gate electrode 131.

The charge trap layer 125 may store introduced charges. Charges (e.g., electrons) existing in the channel layer 115 may flow into the charge trap layer 125 by a tunneling effect, etc. Charges flown into the charge trap layer 125 may be fixed to the charge trap layer 125.

The charge trap layer 125 may be formed by spinodal decomposition through heat treatment. Spinodal phase separation may occur when the formation energy, or Gibbs Free-Energy Change (AG), caused by the mixing of materials included in the charge trap layer 125 at a certain temperature is greater than 0. Spinodal phase separation may be controlled according to the heat treatment temperature of the material included in the charge trap layer 125.

One important reliability factor in semiconductor devices is data retention, that is, the feature of storing charges in the charge trap layer 125 for a longer time. If distances between the memory cells MC are reduced in order to increase memory density in semiconductor devices, movement of trapped charges between memory cells MC may be caused, thereby deteriorating charge retention characteristics.

Charges may move from the charge trap layer 125 to the charge tunneling layer 124 through trap-assisted tunneling or thermal emission. The extent of the charge movement may be determined by the conduction band offset (CBO) at an interface between the charge trap layer 125 and the charge tunneling layer 124.

In a direction parallel to the charge trap layer 125, charge movement may occur by lateral migration according to a charge concentration gradient. The charge movement in a direction parallel to the charge trap layer 125 can be governed by Poole-Frenkel tunneling. The current density due to Poole-Frenkel tunneling may be expressed by the following Poole-Frenkel Conduction Equation (equation 1).

$$J = q μ {N}_{c} E exp ( \frac{- q ( {E}_{T} - \sqrt{qE / πε} )}{kT} ) \qquad ( equation 1 )$$

(J: current Density, q: electronic charge, μ: carrier mobility N_{c}: density of states in conduction band, E: electric field, E_{T}: trap energy, ε: permittivity, k: Boltzmann constant, and T: temperature)

The charge movement in a direction parallel to the charge trap layer 125 by Poole-Frenkel tunneling may be determined by the trap energy E_{T} and trap density NT in the charge trap layer 125. Trap energy refers to a voltage barrier that an electron needs to cross to move from one atom to another within a material. That is, the trap energy represents the depth of the trap state with respect to the conduction band minimum (CBM) of the material. Trap density refers to the number of trapped charges per unit volume. The trap density may be calculated using the charge pumping method. Charge retention characteristics in a direction parallel to the charge trap layer 125 may be improved by higher trap energy and higher trap density.

The charge trap layer 125 may include, for example, at least one material from among silicon nitride (SiN), gallium nitride (GaN), gallium oxide (GaO), hafnium oxide (HfO), scandium oxide (ScO), strontium oxide (SrO), zirconium oxide (ZrO), yttrium oxide (YO), tantalum oxide (TaO), barium oxide (BaO), and zinc sulfide (ZnS).

In some example embodiments, the charge trap layer 125 may include a matrix and nanocrystals provided in the matrix. The matrix may include an amorphous metal oxynitride. The matrix may include metal oxynitride having a permittivity greater than that of silicon nitride. For example, the matrix may include at least one of AlON, ZrON, LaON, AlSiON, HfAlON, LaSiON, AlZrON, LaAlON, HfAlON or ZrSiON. However, example embodiments are not limited thereto. For example, the nanocrystals may include at least one of AlN, GaN, GeN, SIN, CN, InN, YN, ScN or ZrN. However, example embodiments are not limited thereto.

As described above, because the charge trap layer 125 with an amorphous metal oxynitride in which nanocrystals having semiconductor properties are dispersed, the trap energy and trap density may be increased, and the charge retention characteristics may be improved by suppressing the movement of trapped charges between the memory cells MC. Therefore, memory operation characteristics may be improved by reducing the threshold voltage.

The charge blocking layer 126 reduces or prevents charges from leaking from the charge trap layer 125 to the spacer layer 132 and the gate electrode 131. The charge blocking layer 126 may include, but is not limited to, silicon oxide, metal oxide, or metal nitride. The charge blocking layer 126 may include at least one of aluminum oxide, magnesium oxide, aluminum nitride, or gallium nitride. The charge blocking layer 126 may include, for example, SiO₂ or Al₂O₃.

The charge tunneling layer 124 or the charge trap layer 125 may include at least one of TiN, W, Mo, Ru, Pt, or Y at an interface area (or at an edge area) thereof. The above materials may be generated in the charge tunneling layer 124 or the charge trap layer 125 during a process of manufacturing a semiconductor device.

In the semiconductor device 100 according to an example embodiment, the channel layer 115 has a relatively low leakage current by including an amorphous oxide semiconductor and the thermal vulnerability of the oxide semiconductor is improved, thereby improving the electrical characteristics of the channel layer 115.

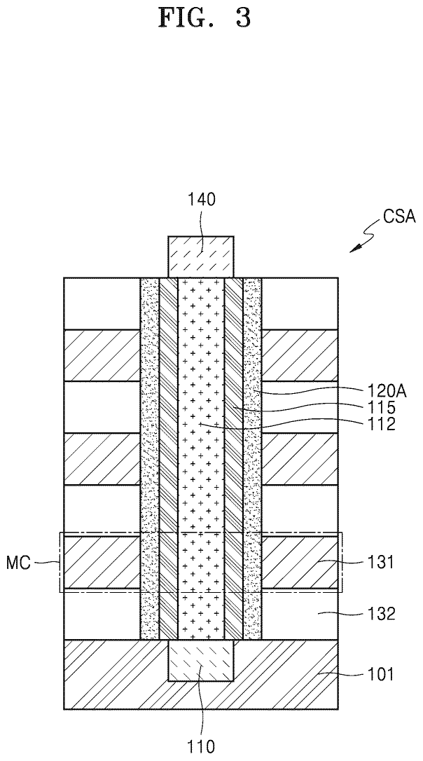

FIG. 3 illustrates an example of a changed gate stack 120A relative to FIG. 2. Components of FIG. 3 using the same reference numbers as those in FIG. 2 have the same configuration and operational effects. Thus, detailed descriptions thereof are omitted below.

A cell string CSA may include a gate stack 120A, and the gate stack 120A may include a ferroelectric material or an antiferroelectric material. The ferroelectric material has ferroelectricity, in which internal electric dipole moments are aligned without an application of an external electric filed and thus spontaneous polarization is maintained. Ferroelectric materials exhibit spontaneous polarization due to permanent dipoles arranged in the same direction and parallel to each other. Ferroelectric materials may have remnant polarization due to dipoles even in the absence of an external electric field. In addition, the direction of polarization may be switched in domain units by an external electric field. The threshold voltage of the semiconductor device 100 may change according to the polarization direction of the ferroelectric material, for example, from the gate electrode 131 toward the channel layer 115, or conversely, from the channel layer 115 toward the gate electrode 131.

Anti-ferroelectric materials may include arrays of electric dipoles, but may have a remnant polarization that is 0 or close to 0. Because the directions of adjacent dipoles are opposite to each other in the absence of an electric field and polarizations thereof cancel each other, the overall spontaneous polarization and remnant polarization may be 0 or close to 0. However, anti-ferroelectric materials may exhibit polarization characteristics and switching characteristics when an external electric field is applied.

The ferroelectric material may include a hafnium oxide material or an aluminum nitride material. The ferroelectric material may have a structure in which a dopant is inserted into a hafnium oxide-based material or a structure in which a dopant is inserted into an aluminum nitride-based material. If the ferroelectric material is a hafnium oxide-based material, the dopant may be Zr, La, Al, Si, or Y. If the ferroelectric material is an aluminum nitride-based material, the dopant may be B or Sc.

In some example embodiments, the ferroelectric material may have at least one structure from among, for example, a fluorite structure, a perovskite structure, and a wurtzite structure.

Ferroelectric materials with a fluorite structure may include, for example, HfO₂ or ZrO₂. Here, HfO₂ or ZrO₂ may have a crystal structure of a tetragonal system or a crystal structure of an orthorhombic system. The crystal structure of a tetragonal system may be antiferroelectric, and the crystal structure of an orthorhombic system may be ferroelectric. Undoped HfO₂ has a stable tetragonal crystal structure, but may also have an orthorhombic crystal structure depending on the grain size. Undoped ZrO₂ may have a stable tetragonal crystal structure. Undoped HfO₂ or ZrO₂ may include nanocrystals having a grain size of, for example, about 1 nm to about 3 nm, but example embodiments are not limited thereto.

Fluorite-based materials may include, for example, HfO₂ or ZrO₂ including a dopant. Here, dopants include, for example, Al, Ga, Co, Ni, Mg, In, La, Y, Nd, Sm, Er, Sr, Ba, or Gd. Dopants may include at least one of Ge, N, or Si. However, these are merely examples. HfO₂ or ZrO₂ including a dopant may have a tetragonal crystal structure with antiferroelectricity or an orthorhombic crystal structure with ferroelectricity according to the grain size and doping concentration. The tetragonal crystal structure is more stable when the grain size is smaller and the doping concentration is greater, and the orthorhombic crystal structure is more stable when the grain size is larger and the doping concentration is lower.

HfO₂ or ZrO₂ that is doped may include nanocrystals having a larger grain size compared to the undoped HfO₂ or ZrO₂ described above. For example, HfO₂ or ZrO₂ doped with a dopant may have a grain size of about 4 nm to about 7 nm, or about 4 nm to about 5 nm, but example embodiments are not limited thereto.

The concentration of the dopant may vary according to the type of dopant. For example, when the dopant is Si, the doping concentration may be about 1 at % (atomic percent) to about 5 at %. However, example embodiments are not limited thereto.

Ferroelectric materials with a perovskite structure may include materials having a composition of M¹M²O₃ (M¹M² is a metal element). The perovskite material may include, for example, at least one of PbZrO₃, PbTiO₃, BaTiO₃, SrTiO₃, or CaTiO₃. However, example embodiments are not limited thereto. Perovskite materials may have a tetragonal crystal structure with antiferroelectricity or an orthorhombic crystal structure with ferroelectricity according to the composition ratio of the constituent elements.

The wurtzite material may include undoped AlN, GaN or InN, or may include AlN, GaN or InN including a dopant. The dopant may include at least one of boron (B) or scandium (Sc).

For example, the gate stack 120A may include hafnium zirconium oxide and have Zr/(Hf+Zr) in the range of about 20 at % to about 80 at %. The gate stack 120A may include at least one of TiN, W, Mo, Ru, Pt, or Y at an interface area thereof with the channel layer 115 (e.g., at an edge area of the gate stack 102A interfacing with the channel layer 115).

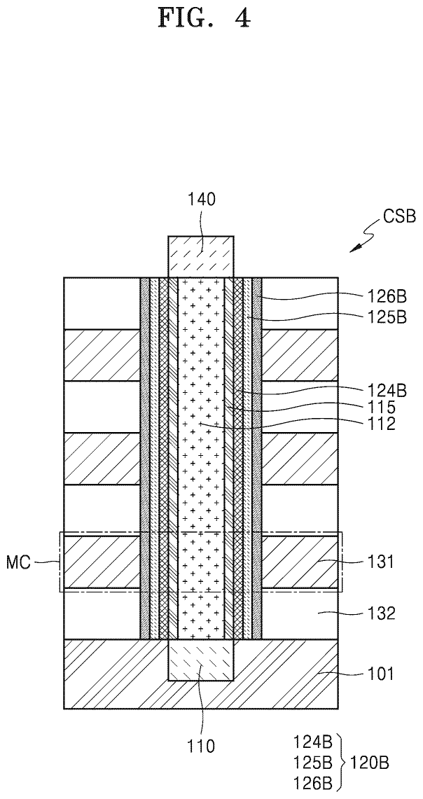

FIG. 4 illustrates an example of a changed gate stack 120B relative to FIG. 2. Components of FIG. 4 using the same reference numbers as those in FIG. 2 have the same configuration and operational effects. Thus, detailed descriptions thereof are omitted below.

A cell string CSB may include the gate stack 120B, and the gate stack 120B may include a high permittivity layer 124B provided on a sidewall of the channel layer 115, a ferroelectric layer 125B provided on a sidewall of the high permittivity layer 124B, and a silicon oxide layer 126B provided on a sidewall of the ferroelectric layer 125B. The ferroelectric layer 125B may include at least one of TiN, W, Mo, Ru, Pt, or Y at an interface area thereof with the high permittivity layer 124B (e.g., at an edge area of the ferroelectric layer 125B interfacing with the high permittivity layer 124B).

The high permittivity layer 124B may include a material having a higher permittivity than that of silicon oxide. The high permittivity layer 124B may include at least one of hafnium oxide, zirconium oxide, or lanthanum oxide. The high permittivity layer 124B may include, for example, at least one of HfO₂, ZrO₂, or La₂O₃.

As described above, in the semiconductor device 100 according to some example embodiments, the channel layer 115 includes an oxide semiconductor and the thermal stability of the oxide semiconductor is secured, thereby having a relatively low leakage current and/or a relatively high on-current. The semiconductor devices 100, 100A and 100B may be applied to a non-volatile memory device.

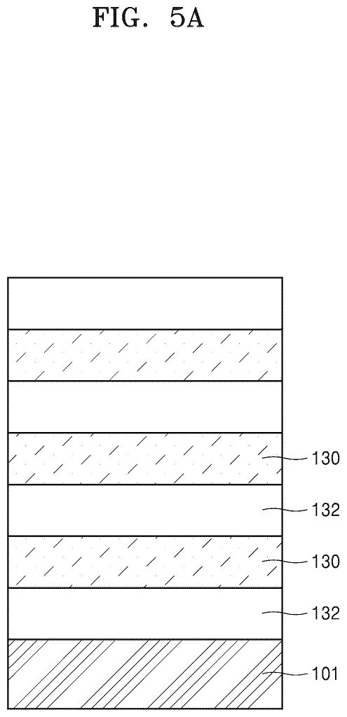

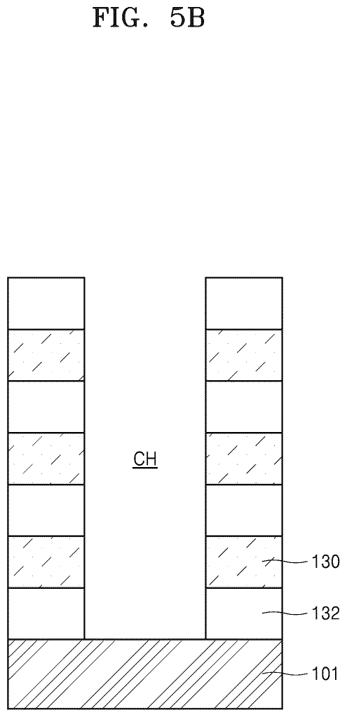

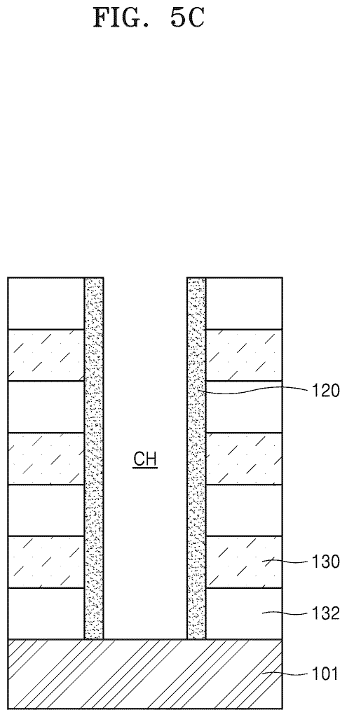

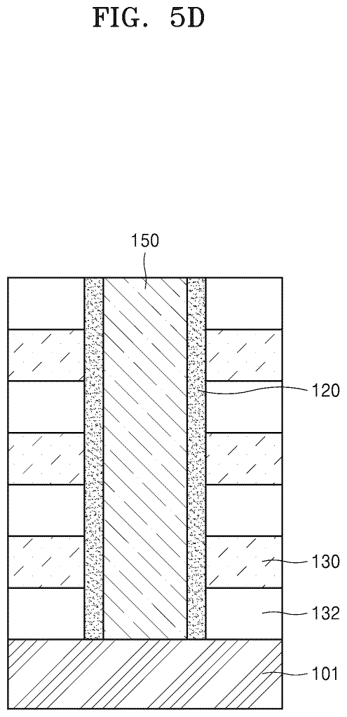

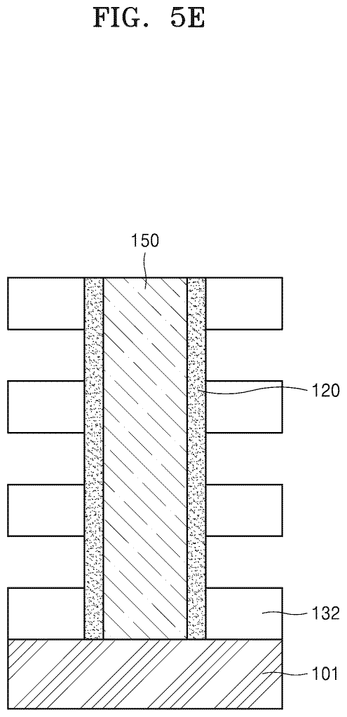

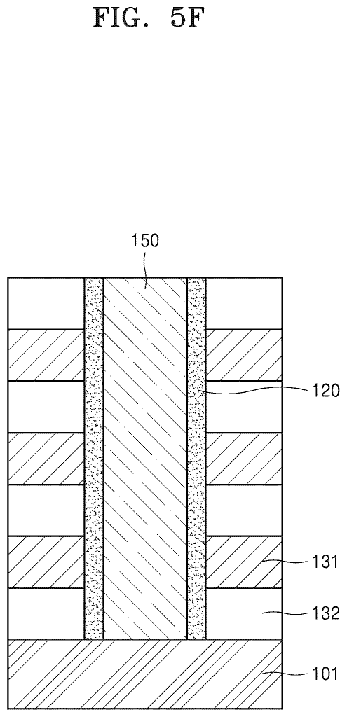

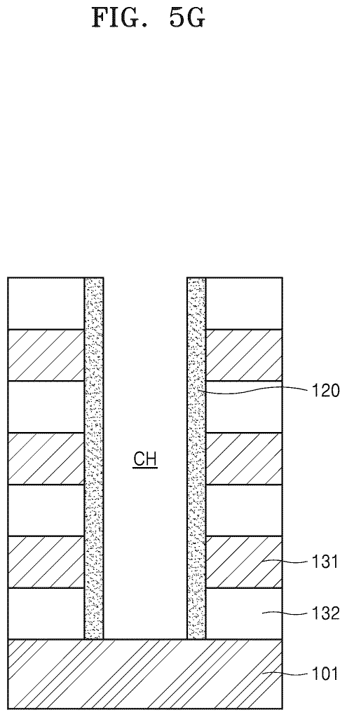

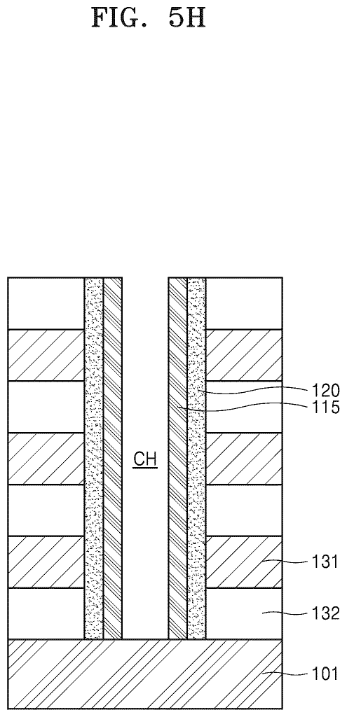

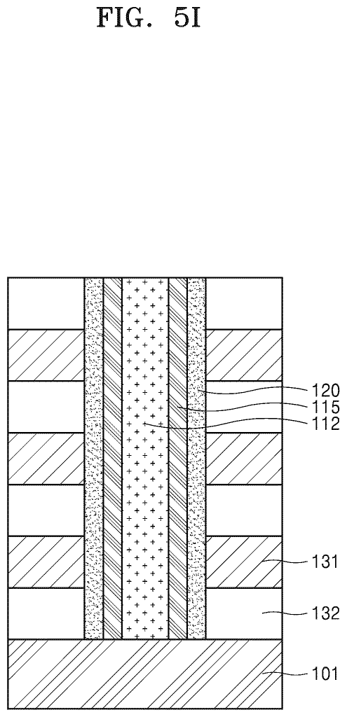

Hereinafter, with reference to FIGS. 5A to 51, a method of manufacturing the semiconductor device according to an example embodiment will be described.

Referring to FIG. 5A, a mold layer 130 and the spacer layer 132 are alternately laminated on the substrate 101. The spacer layer 132 may include, but is not limited to, silicon oxide, silicon nitride, etc. The spacer layer 132 may include, for example, SiO₂. The mold layer 130 may include, for example, silicon nitride.

Referring to FIG. 5B, the channel hole CH is formed to penetrate a laminate of the spacer layer 132 and the mold layer 130. The channel hole CH may extend in a direction perpendicular to the surface of the substrate 101. The channel hole CH may have a circular cross-section. The channel hole CH may be formed by anisotropic etching of the spacer layer 132 and the mold layer 130.

Referring to FIG. 5C, the gate stack 120 may be formed in the channel hole CH. The gate stack 120 may be formed of a single layer or of multiple layers. The gate stack 120 may be formed by a physical vapor deposition method, a chemical vapor deposition method, or an atomic layer deposition method. The gate stack 120 may include the charge blocking layer 126, the charge trap layer 125, and the charge tunneling layer 124 sequentially formed inside the channel hole CH, as illustrated in FIG. 2.

Referring to FIG. 5D, a sacrificial layer 150 may be formed on an inner wall of the gate stack 120. The sacrificial layer 150 may include at least one of silicon oxide, silicon nitride, aluminum oxide, aluminum nitride, or metal. The metal may include, for example, at least one of TiN, W, Mo, Ru, Pt, or Y. The process of forming a sacrificial layer 150 may be performed optionally.

Referring to FIG. 5E, the mold layer 130 may be removed through selective etching. Even if the mold layer 130 is removed, the spacer layer 132 may be supported by the gate stack 120 and the sacrificial layer 150. Referring to FIG. 5F, the gate electrode 131 may be formed in a space where the mold layer 130 has been removed. In this manner, the gate electrode 131 and the spacer layer 132 may be alternately stacked. Referring to FIG. 5G, the sacrificial layer 150 may be removed. Referring to FIG. 5H, the channel layer 115 may be formed in the channel hole CH formed by removing the sacrificial layer 150. In the method of manufacturing the semiconductor device manufacturing method according to an example embodiment, the channel layer 115 may be formed after the gate electrode 131 is formed. The channel layer 115 may be formed on an inner wall of the channel hole CH (e.g., formed inside the channel hole CH). The channel layer 115 may be formed by atomic layer deposition. The channel layer 115 may be an oxide including at least one of In, Ga, Zn, W, Sn, or Hf. The channel layer 115 may include ZIO, IGO, or IGZO. The channel layer 115 may include InGaZnO, ZrInZnO, InGaZnO₄, ZnInO, In₂O₃, HfInZnO, or a combination thereof.

Referring to FIG. 5I, an area of the channel hole CH remaining unfilled after forming the channel layer may be filled with the filler 112. The filler 112 may include silicon oxide or silicon nitride.

As described above, in the method of manufacturing the semiconductor device according to an example embodiment, the channel layer 115 may be formed after a laminate of the gate electrode 131 and the spacer layer 132 is formed. The manufacturing process of the semiconductor device includes numerous processes that are performed at relatively high temperatures of 600° C. or greater. For example, a process of laminating the mold layer 130 and the spacer layer 132 described with reference to FIG. 5A is performed in a temperature of about 600° C. to about 800° C., and processes of removing the mold layer 130 and forming the gate electrode 131 described with reference to FIGS. 5E and 5F are performed at 800° C. or higher. When the channel layer 115 is formed of an oxide semiconductor, since the oxide semiconductor has relatively low thermal stability, if a relatively high temperature process of 600° C. or greater is performed when the channel layer 115 is formed, the channel layer 115 may deteriorate, and thus the electrical characteristics may deteriorate. In the method of manufacturing the semiconductor device according to an example embodiment, because the channel layer 115 is formed after the gate electrode 131 process performed at a relatively high temperature, electrical characteristics of the channel layer 115 may be maintained without deterioration.

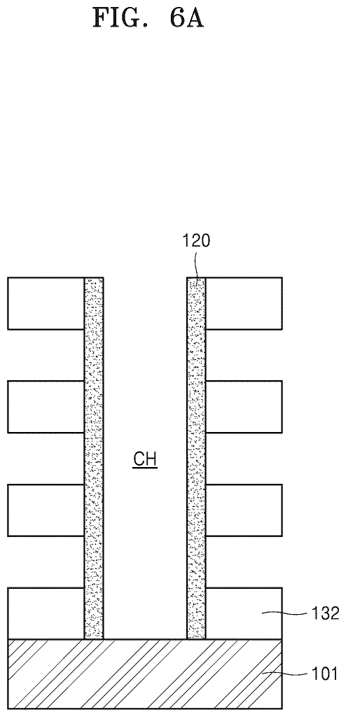

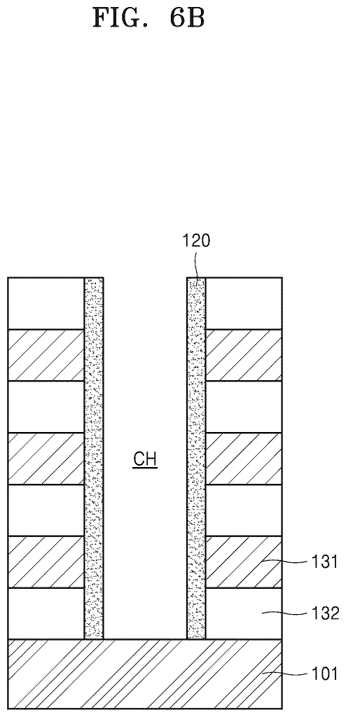

The following FIGS. 6A and 6B illustrate a process in which the process of forming the sacrificial layer 150 is omitted in the process illustrated with reference to FIGS. 5D to 5G.

Referring to FIG. 6A, when the spacer layer 132 may be supported by the gate stack 120 alone when the mold layer 130 is removed, the process of forming the sacrificial layer 150 may be omitted. Referring to FIG. 5C and FIG. 6A, after forming the gate stack 120, the mold layer 130 may be removed without forming the sacrificial layer 150. Then, referring to FIG. 6B, the gate electrode 131 may be formed at a location where the mold layer 130 has been removed. The process after forming the gate electrode 131 is the same as in FIGS. 5H and 51, so a detailed description is omitted below.

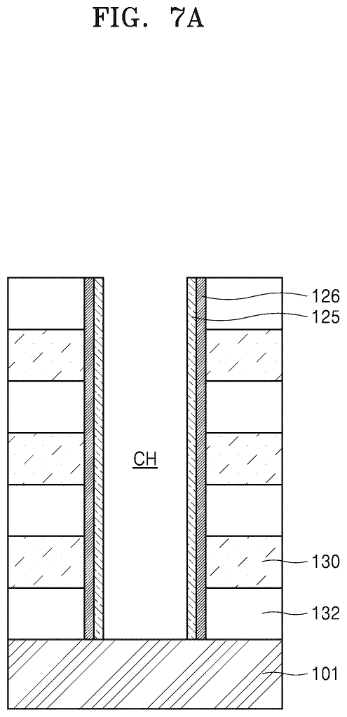

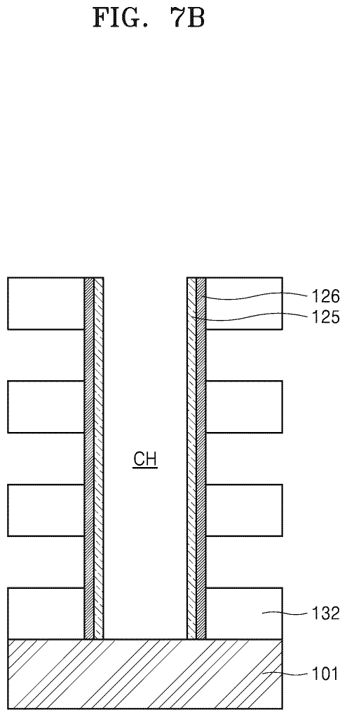

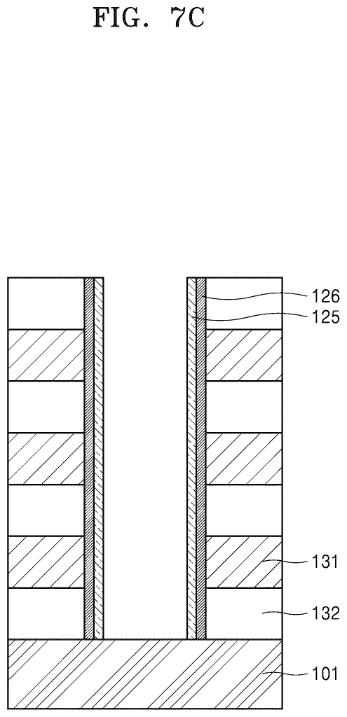

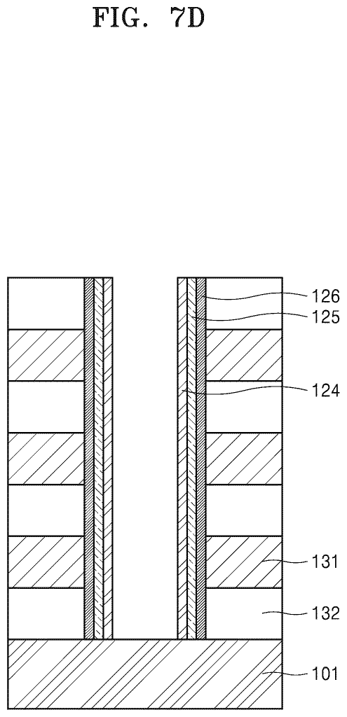

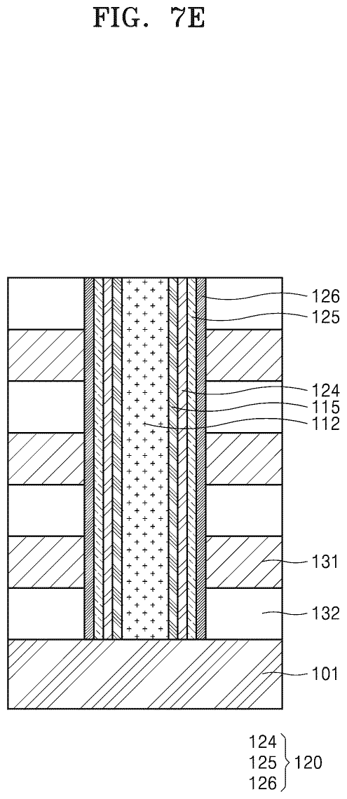

Hereinafter, with reference to FIGS. 7A to 7E, a method of manufacturing the semiconductor device according to an example embodiment is described.

Some components of FIGS. 7A to 7E using the same reference numbers as those in FIGS. 5A to 51 have substantially the same configuration and operational effects. Thus, redundant descriptions will be omitted and differences will be mainly described.

Referring to FIG. 7A, the charge blocking layer 126 and the charge trap layer 125 are formed in the channel hole CH of a structure in which the mold layer 130 and the spacer layer 132 are laminated. Because the charge blocking layer 126 and the charge trap layer 125 are the same as those described with reference to FIG. 2, the detailed description is omitted. When the gate stack includes a plurality of layers, some of the plurality of layers may be formed first. Here, as illustrated in FIG. 2, a case in which the gate stack includes the charge blocking layer 126, the charge trap layer 125, and the charge tunneling layer 124 is described.

Referring to FIG. 7B, the mold layer 130 may be removed. Even if the mold layer 130 is removed, the spacer layer 132 may be supported by the charge blocking layer 126 and the charge trap layer 125. Referring to FIG. 7C, the gate electrode 131 may be formed at a location where the mold layer 130 has been removed. Referring to FIG. 7D, the charge tunneling layer 124 may be formed on an inner side of the charge trap layer 125. Referring to FIG. 7E, the channel layer 115 may be formed on an inner side of the charge tunneling layer 124, and the filler 112 may be formed on an inner side of the channel layer 115.

As in the present example embodiment, some layers of the gate stack 120 may be formed before the formation of the gate electrode 131, and the remaining layers of the gate stack 120 may be formed after the formation of the gate electrode 131. In the present example embodiment, processing the sacrificial layer may not be needed.

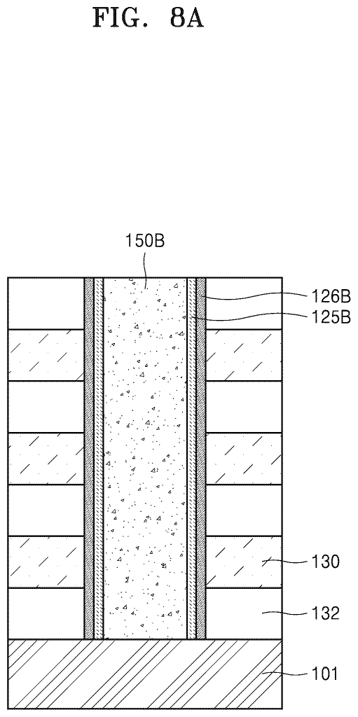

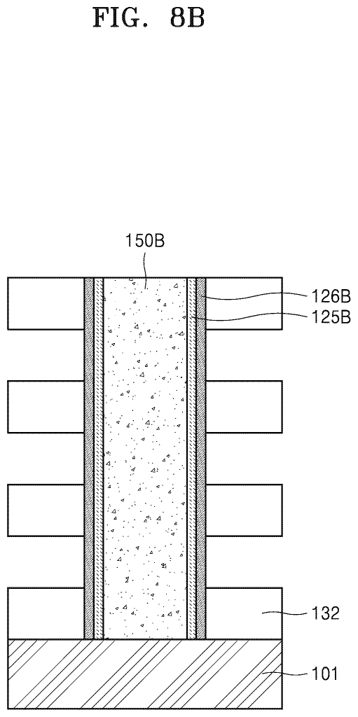

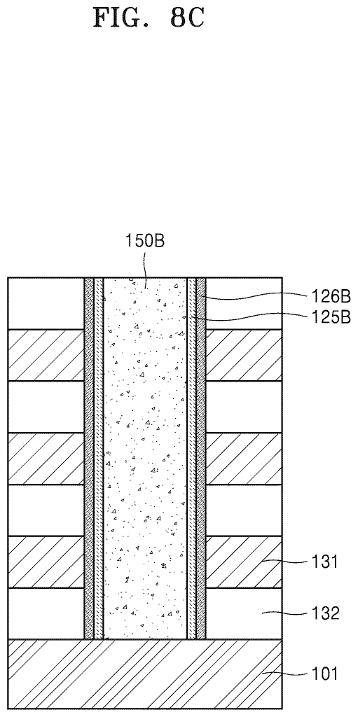

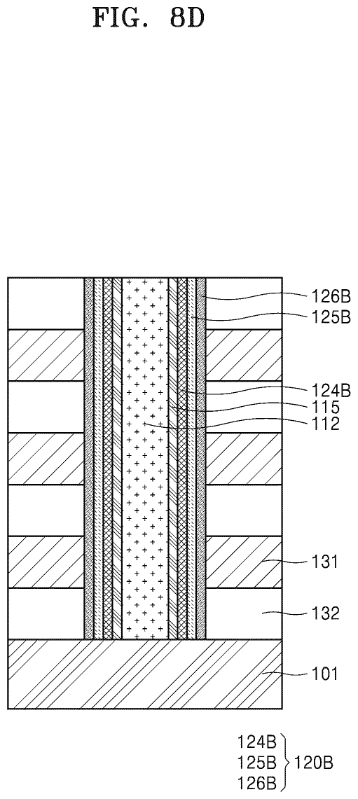

With reference to FIGS. 8A to 8D, a method of manufacturing the semiconductor device according to an example embodiment is described.

Referring to FIG. 8A, the silicon oxide layer 126B and the ferroelectric layer 125B may be formed in the channel hole CH formed in a laminated structure of the mold layer 130 and the spacer layer 132. The forming of the ferroelectric layer 125B may include forming a ferroelectric precursor layer and heat-treating the ferroelectric precursor layer. The ferroelectric precursor layer may represent an amorphous layer before the ferroelectric material crystallizes. The ferroelectric precursor layer may be formed by physical vapor deposition, chemical vapor deposition, or atomic layer deposition. In addition, a sacrificial layer 150B may be formed on an inner side of the ferroelectric layer 125B. The sacrificial layer 150B may include at least one of TiN, W, Mo, Ru, Pt, or Y. Also, the ferroelectric layer 125B may have a ferroelectric phase through the heat treatment process. The heat treatment process may be performed at a temperature ranging from about 400° C. to about 1,000° C., or from about 420° C. to about 800° C. Because the sacrificial layer 150B includes a metal material, a ferroelectric phase of the ferroelectric layer 125B may be induced as a reaction occurs between the sacrificial layer 150B and the ferroelectric layer 125B during the heat treatment process.

Referring to FIG. 8B, the mold layer 130 may be removed. Referring to FIG. 8C, the gate electrode 131 may be formed at a location where the mold layer 130 has been removed. Referring to FIG. 8D, the sacrificial layer 150B may be removed after the gate electrode 131 is formed. Even if the sacrificial layer 150B is removed, some of the sacrificial layer 150B material may remain at the interface area of the ferroelectric layer 125B (e.g., at an edge area of the ferroelectric layer 125B that has interfaced with the sacrificial layer 150B before the sacrificial layer 150B has been removed). Thus, at least one of TiN, W, Mo, Ru, Pt, or Y may be included at the interface area of the ferroelectric layer 125B.

A high permittivity layer 124B may be formed on the inner side of the ferroelectric layer 125B, and the channel layer 115 may be formed on the inner side of the high permittivity layer 124B. The channel layer 115 may include an oxide semiconductor. Additionally, a filler 112 may be formed on the inner side of the channel layer 115. In the present example embodiment, the gate stack 120B may include the high permittivity layer 124B, the ferroelectric layer 125B, and the silicon oxide layer 126B. As described above, in the manufacturing method according to an example embodiment, some layers of the gate stack 120B may be formed first, the gate electrode 131 may be formed, and then the remaining layers of the gate stack 120B may be formed.

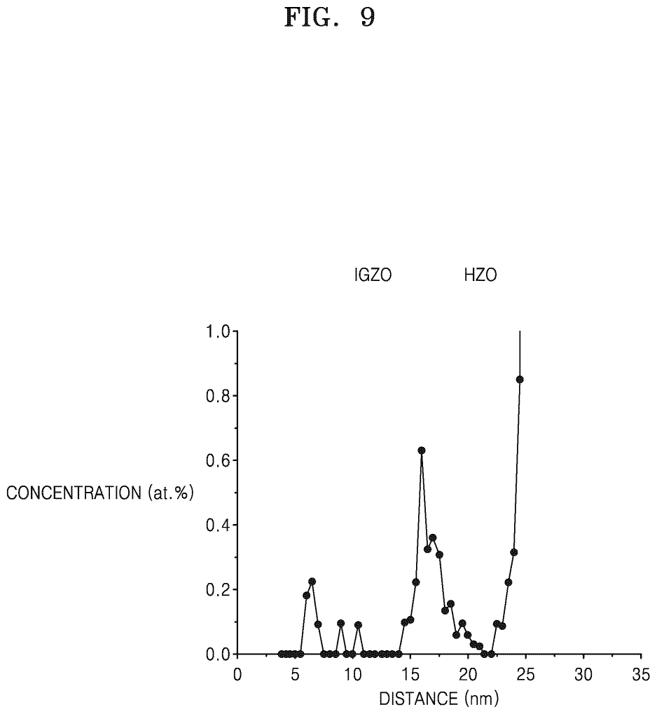

FIG. 9 shows a result of analyzing the semiconductor device by using an atom probe tomography (APT) analysis method according to an example embodiment. The graph shows the Mo concentration according to the distance of the semiconductor device manufactured according to the manufacturing method according to an example embodiment. A semiconductor device according to an example embodiment includes an IGZO channel layer having a thickness of 10 nm and a Hafnium Zirconium Oxide (HZO) ferroelectric layer having a thickness of 10 nm. The above example embodiment represents a case in which the gate stack includes the HZO ferroelectric layer. Also, the sacrificial layer includes Mo. According to a manufacturing method according to an example embodiment, a HZO ferroelectric layer is formed with a gate stack, a Mo sacrificial layer is formed in a channel hole, and then heat treatment is performed. Then, the mold layer is removed, a gate electrode is formed at a location where the mold layer has been removed, and the Mo sacrificial layer is removed. A channel layer is formed in the channel hole from which the Mo sacrificial layer has been removed. As a result of APT analysis of the semiconductor device formed by the above process, Mo was detected at an interface area (e.g., an edge area) of the HZO gate stack. In FIG. 9, a horizontal axis represents the distance from the IGZO channel layer of the semiconductor device to the HZO gate stack, and the vertical axis represents the concentration of Mo. Here, the concentration of Mo represents the ratio of the content of Mo to the total constituent element content of a layer. Referring to the graph in FIG. 9, it is shown that approximately 0.6 at % Mo exists at an interface area of the HZO gate stack with the IGZO channel layer (e.g., at an edge area of the HZO gate stack that interfaces with the IGZO channel layer). As described above, the gate stack of the semiconductor device according to an example embodiment may include at least one layer and the at least one layer may include at least one of TiN, W, Mo, Ru, Pt, or Y at an interface area thereof. In addition, the content of at least one of TiN, W, Mo, Ru, Pt, or Y may be in a range of about 0.5 at % to about 2 at %.

The semiconductor device includes a plurality of memory cells that retain information even when power is removed and use stored information when power is restored. The semiconductor device may be widely applied to mobile phones, digital cameras, personal digital assistants (PDAs), portable computing devices, etc.

FIG. 10 illustrates a circuit diagram including the semiconductor device according to an example embodiment. The semiconductor device may be a non-volatile memory device. k*n cell strings CS may be provided and arranged in the form of a matrix, and may be named CSij (1≤i≤k, 1≤j≤n) according to each row and column position. Each cell string CSij may be connected to a bit line BL, a string selection line SSL, a word line WL, and a common source line CSL.

Each cell string CSij includes memory cells MC and a string selection transistor SST. The memory cells MC and the string selection transistor SST of each cell string CSij may be stacked in a height direction.

Rows of a plurality of cell strings CS are respectively connected to different string selection lines SSL1 to SSLk. For example, the string selection transistors SST of the cell strings CS11 to CS1n are commonly connected to the string selection line SSL1. The string selection transistors SST of the cell strings CSK1 to CSkn are commonly connected to the string selection line SSLK.

Columns of the plurality of cell strings CS are respectively connected to different bit lines BL1 to BLn. For example, the memory cells MC of the cell strings CS11 to CSK1 and the string selection transistors SST may be commonly connected to the bit line BL1, and the memory cells MC of the cell strings CS1n to CSkn and the string selection transistors SST may be commonly connected to the bit line BLn.

The rows of the plurality of cell strings CS may be respectively connected to different common source lines CSL1 to CSLk. For example, the string selection transistors SST of the cell strings CS11 to CSIn may be commonly connected to the common source line CSL1, and the string selection transistors SST of the cell strings CSK1 to CSkn may be commonly connected to the common source line CSLk.

The memory cells MC at the same height from the substrate or the string selection transistors SST are commonly connected to one word line WL and the memory cells MC at different heights from the substrate or the string selection transistors SST may be respectively connected to different word lines WL1 to WLm.

The illustrated circuit structure is an example. For example, the number of rows of the cell strings CS may be increased or reduced. As the number of rows of cell strings CS is changed, the number of string selection lines SSL connected to rows of the cell strings CS and the number of cell strings CS connected to one bit line BL may also be changed. As the number of rows of cell strings CS is changed, the number of common source lines CSL connected to the rows of cell strings CS may also be changed.

The number of columns of the cell strings CS may be increased or reduced. As the number of columns of the cell string CS is changed, the number of bit lines BL connected to the columns of the cell strings CS and the number of cell strings CS connected to one string selection line SSL may also be changed.

The height of the cell string CS may also be increased or reduced. For example, the number of memory cells MC stacked in each of the cell strings CS may be increased or reduced. As the number of memory cells MC stacked in each of the cell strings CS is changed, the number of word lines WL may also be changed. For example, the string selection transistor SST provided to each of the cell strings CS may be increased. As the number of string selection transistors SST provided to each of the cell strings CS is changed, the number of string selection lines SSL or common source lines CSL may also be changed. When the number of string selection transistors SST increases, the string selection transistors SST may be stacked in the same shape as the memory cells MC.

For example, writing and reading operations may be performed in units of rows of the cell strings CS. Cell strings CS may be selected in units of one row by the common source line CSL, and cell strings CS may be selected in a row unit by the string selection lines SSL. Also, a voltage may be applied to the common source lines CSL using at least two common source lines CSL as a unit. Also, a voltage may be applied to the common source lines CSL using the entire common source lines CSL as a unit.

In a selected row of the cell strings CS, the writing and reading operations may be performed in units of pages. The page may be one row of memory cells MC connected to one word line WL. In the selected row of cell strings CS, memory cells MC may be selected in units of pages by word lines WL. For example, each gate electrode 131 of FIG. 1 may be connected to one of the word line WL or the string selection line SSL.

The memory cell MC has a circuit structure in which a transistor including the gate electrode 131, the spacer layer 132, and the channel layer 115 is connected to the charge trap layer 125.

The memory cell MC is continuously arranged in the vertical direction (the Z-direction) to construct the cell string CS. Also, opposite ends of the cell string CS may be connected to the common source line CSL and the bit line BL as shown in the circuit diagram of FIG. 10. When the voltage is applied to the common source line CSL and the bit line BL, the programming, reading, and erasing operations may be performed on the plurality of memory cells MC.

For example, when a memory cell MC to be programmed is selected, a gate voltage value of the corresponding memory cell MC is adjusted so that a channel is not formed in the selected memory cell MC, that is, the channel is in an OFF state, and for the unselected memory cells MC, a gate voltage value of the memory cells MC is adjusted so that the channel is in an ON state. Accordingly, a charge tunnels through the charge tunneling layer 124 by a voltage applied to the common source line CSL and the charge trap layer 125 of the selected memory cell MC, thereby programming the desired 1 or 0 information in the selected memory cell MC.

In a read operation, similar to the write operation, reading of a selected cell may be performed. That is, after a gate voltage applied to each of the gate electrodes 131 is adjusted so that the selected memory cell MC is channel-off state and the unselected memory cells MC are channel-on state, a memory cell MC state (1 or 0) may be checked by measuring a current flowing through the corresponding memory cell MC by an applied voltage V_{read} between the common source line CSL and the bit line BL.

The semiconductor device 100 has a structure in which cells are connected in a vertical direction. When information is stored, charges may diffuse vertically and move to adjacent cells, thereby affecting the operation of adjacent cells. However, the semiconductor device 100 may reduce adverse effects on the operation of adjacent cells by suppressing lateral charge loss by including the nanocrystal region and the isolation region in the charge trap layer 125.

The semiconductor device according to an example embodiment, which has the features described above, may be applied to various electronic apparatuses.

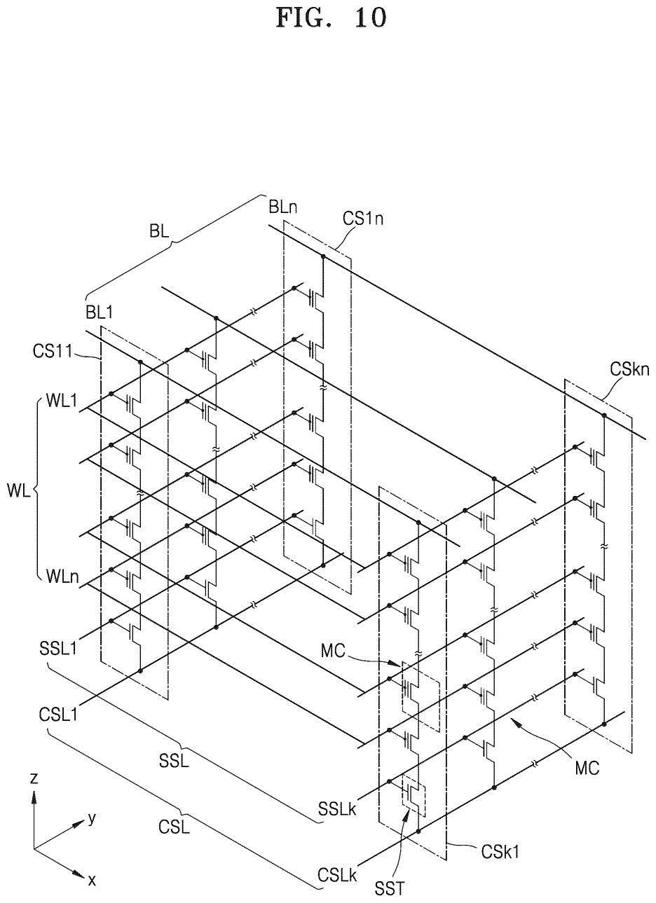

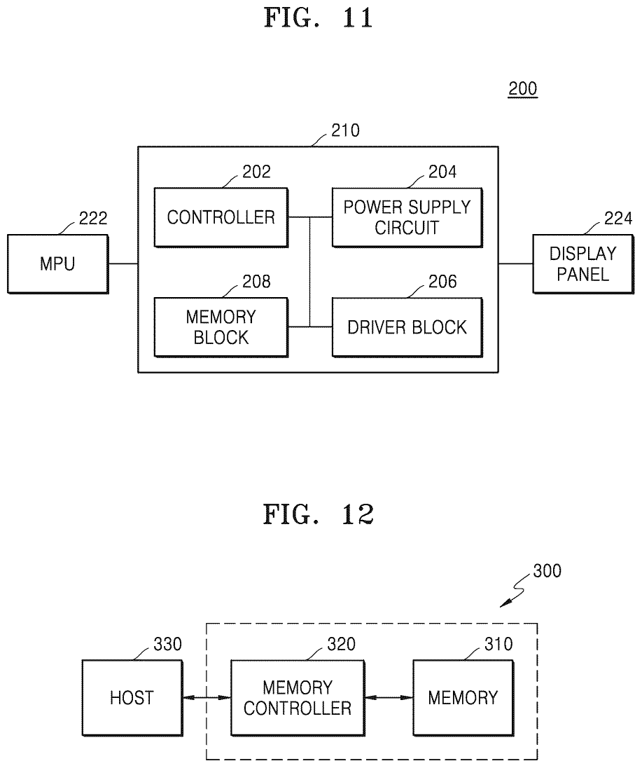

FIG. 11 is a schematic block diagram of a display apparatus 200 including a display driver integrated circuit (DDI) 210 according to an example embodiment. Referring to FIG. 11, the DDI 210 may include a controller 202, a power supply circuit 204, a driver block 206, and a memory block 208. The controller 202 receives and decodes a command from a main processing unit (MPU) 222, and controls each block of the DDI 210 to implement an operation according to the command. The power supply circuit 204 generates a driving voltage in response to the control of the controller 202. The driver block 206 drives a display panel 224 by using the driving voltage generated from the power supply circuit 204 in response to the control of the controller 202. The display panel 224 may be, for example, a liquid crystal display panel, an organic light-emitting device (OLED) display panel, or a plasma display panel. The memory block 208 is a block that temporarily stores commands input to the controller 202 or control signals output from the controller 202, or stores necessary data, and may include memory devices such as a random access memory (RAM), a read only memory (ROM), a dynamic random access memory (DRAM), and NOT AND (NAND). For example, the memory block 208 may include the semiconductor device 100 according to the example embodiments described above.

FIG. 12 is a block diagram illustrating an electronic apparatus 300 according to an example embodiment. Referring to FIG. 12, the electronic apparatus 300 includes a memory 310 and a memory controller 320. The memory controller 320 may control the memory 310 to read data from the memory 310 and/or write data to the memory 310 in response to a request from a host 330. The memory 310 may include the semiconductor device 100 according to the example embodiments described above.

FIG. 13 is a block diagram of an electronic apparatus 400 according to an example embodiment. Referring to FIG. 13, an electronic apparatus 400 may constitute a wireless communication device, or a device capable of transmitting and/or receiving information in a wireless environment. The electronic apparatus 400 includes a controller 410, an input/output device (I/O) 420, a memory 430, and a wireless interface 440, which are each interconnected via a bus 450.

The controller 410 may include at least one of a microprocessor, a digital signal processor, or a similar processing device. The I/O 420 may include at least one of a keypad, a keyboard, or a display. The memory 430 may be used to store commands executed by the controller 410. For example, the memory 430 may be used to store user data. The electronic apparatus 400 may use the wireless interface 440 to transmit/receive data via a wireless communication network. The wireless interface 440 may include an antenna and/or a wireless transceiver. In some example embodiments, the electronic apparatus 400 may be used for communication interface protocols of third generation communication systems, such as code division multiple access (CDMA), global system for mobile communications (GSM), north American digital cellular (NADC), extended-time division multiple access (E-TDMA), and/or wide band code division multiple access (WCDMA). The memory 430 of the electronic apparatus 400 may include the semiconductor device 100 according to the example embodiments described above.

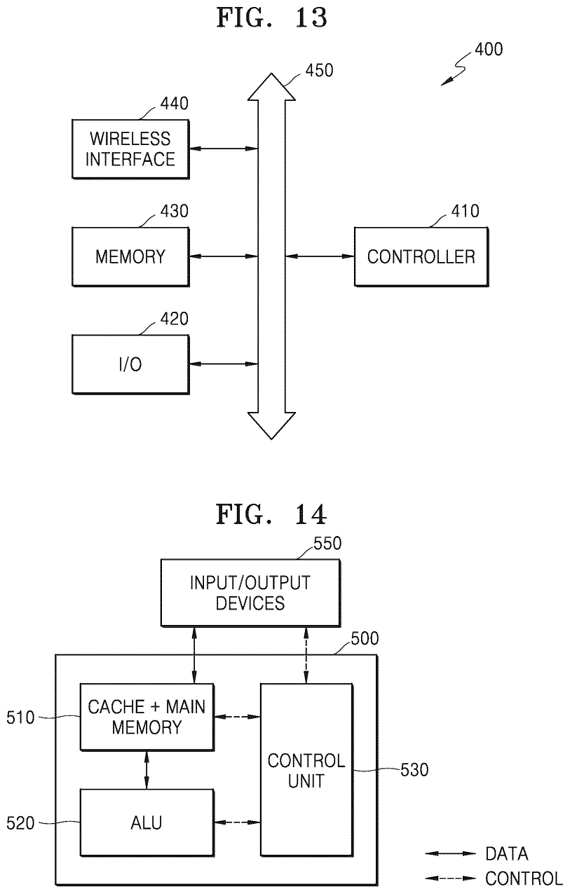

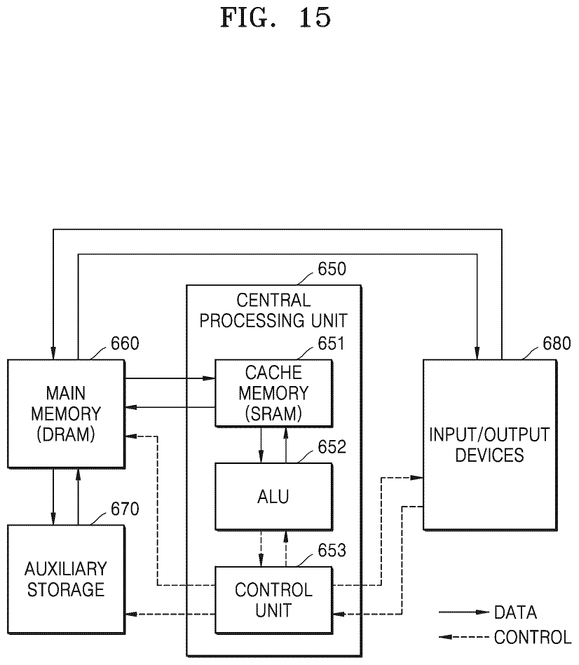

FIGS. 14 and 15 are conceptual diagrams schematically showing device architectures that may be applied to an electronic apparatus according to an example embodiment.

Referring to FIG. 14, the electronic device architecture 500 may include a memory unit 510 and a control unit 530, and may further include an arithmetic logic unit (ALU) 520. The memory unit 510, the ALU 520, and the control unit 530 may be electrically connected to each other. For example, the electronic device architecture 500 may be implemented as a single chip including the memory unit 510, the ALU 520, and the control unit 530. For example, the memory unit 510, the ALU 520, and the control unit 530 may be interconnected by a metal line on an on-chip and communicate directly with each other. The memory unit 510, the ALU 520, and the control unit 530 may be integrated on one substrate 101 (FIG. 1) in a monolithic manner and constitute a single chip. I/O devices 550 may be connected to the electronic device architecture (chip) 500. Additionally, the memory unit 510 may include both main memory and cache memory. Such electronic device architecture (chip) 500 may be an on-chip memory processing unit. The memory unit 510, ALU 520 and/or control unit 530 may each independently include the semiconductor device 100 according to the example embodiments described above.

Referring to FIG. 15, a cache memory 651, an ALU 652, and a control unit 653 may constitute a central processing unit (CPU) 650, and the cache memory 651 may be formed of or include a static random access memory (SRAM). Apart from the CPU 650, a main memory 660, an auxiliary storage 670, and an I/O devices 680 may be provided. The main memory 660 may be, for example, a DRAM.

In some cases, the electronic device architecture may be implemented in a single chip in which computing unit devices and memory unit devices are adjacent to each other, without distinction between sub-units.

Semiconductor devices according to some example embodiments may be applied to various user devices, such as computers, portable computers, Ultra Mobile PCs (UMPCs), workstations, net-books, PDAs, portable computers, web tablets, wireless phones, mobile phones, smart phones, digital cameras, digital audio recorders, digital audio players, digital picture recorders, digital picture players, digital video recorders, digital video players, devices capable of transmitting and receiving information in a wireless environment, and home networks.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The semiconductor devices according to the above example embodiments may have a relatively low leakage current by including an oxide semiconductor channel layer.

The methods of manufacturing the semiconductor device according to the above example embodiments may include forming a gate electrode stacked structure and then forming the oxide semiconductor channel layer, thereby improving the thermal stability of the oxide semiconductor channel layer.

The electronic apparatuses according to the example embodiment may stably implement relatively high capacity and/or relatively high performance by including relatively highly integrated relatively small semiconductor devices.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A method of manufacturing a semiconductor device, the method comprising:
alternately stacking a spacer layer and a mold layer;
etching the spacer layer and the mold layer to form a channel hole penetrating therethrough;
forming a gate stack inside the channel hole;
removing the mold layer;
forming a gate electrode in a space where the mold layer has been removed; and
after the forming the gate electrode, forming a channel layer including an oxide semiconductor on the gate stack.

2. The method of claim 1, further comprising:
forming a sacrificial layer on the gate stack after the forming the gate stack and before the removing the mold layer.

3. The method of claim 2, further comprising:
removing the sacrificial layer after the removing the mold layer.

4. The method of claim 1, wherein the forming the gate stack comprises depositing a ferroelectric precursor and heat-treating the ferroelectric precursor.

5. The method of claim 4, wherein the heat-treating is performed in a range of about 400° C. to about 1,000° C.

6. The method of claim 2, wherein the sacrificial layer comprises silicon oxide, silicon nitride, aluminum oxide, or aluminum nitride.

7. The method of claim 2, wherein the sacrificial layer comprises at least one of TiN, W, Mo, Ru, Pt, or Y.

8. The method of claim 7, wherein
the gate stack comprises at least one layer, and
an interface area of the at least one layer includes at least one of TiN, W, Mo, Ru, Pt, or Y after the sacrificial layer is removed.

9. The method of claim 8, wherein
the gate stack comprises a channel blocking layer, a charge trap layer, and a charge tunneling layer sequentially provided on an inner side of the channel hole, and
an interface area of the charge tunneling layer or the charge trap layer includes at least one of TiN, W, Mo, Ru, Pt, or Y.

10. The method of claim 8, wherein
the gate stack comprises a ferroelectric layer, and
the ferroelectric layer comprises at least one of TiN, W, Mo, Ru, Pt, or Y in an interface area thereof with the channel layer.

11. The method of claim 8, wherein
the gate stack comprises a silicon oxide layer, a ferroelectric layer, and a high permittivity layer stacked sequentially on an inner side of the channel hole, and
an interface area of the ferroelectric layer includes at least one of TiN, W, Mo, Ru, Pt, or Y.

12. The method of claim 8, wherein the mold layer comprises silicon nitride.

13. A semiconductor device comprising:
a gate electrode and a spacer layer alternating on each other, a stack structure of the gate electrode and the spacer layer including a channel hole penetrating therethrough;
a gate stack on an inner side of the channel hole; and
a channel layer on the gate stack and including an oxide semiconductor,
wherein the gate stack comprises at least one layer, and an interface area of the at least one layer includes at least one of TiN, W, Mo, Ru, Pt, or Y at a range of about 0.5 at % to about 2 at %.

14. The semiconductor device of claim 13, wherein
the gate stack comprises a ferroelectric layer, and
the ferroelectric layer includes at least one of TiN, W, Mo, Ru, Pt, or Y is included in an interface area thereof with the channel layer.

15. The semiconductor device of claim 13, wherein
the gate stack comprises a silicon oxide layer, a ferroelectric layer, and a high permittivity layer stacked sequentially on the inner side of the channel hole, and
an interface area of the ferroelectric layer includes at least one of TiN, W, Mo, Ru, Pt, or Y.

16. The semiconductor device of claim 13, wherein the spacer layer comprises silicon oxide, a metal organic framework, or boron nitride.

17. An electronic apparatus comprising:
a host;
a semiconductor device; and
a memory controller configured to control the semiconductor device to perform at least one of reading data from or writing data on the semiconductor device in response to a request of the host,
wherein the semiconductor device comprises
a gate electrode and a spacer layer alternating on each other, a stack structure of the gate electrode and the spacer layer including a channel hole penetrating therethrough,
a gate stack on an inner side of the channel hole; and
a channel layer on the gate stack and including an oxide semiconductor, and
wherein the gate stack comprises at least one layer, and an interface area of the at least one layer includes at least one of TiN, W, Mo, Ru, Pt, and Y at a range of about 0.5 at % to about 2 at %.

18. The electronic apparatus of claim 17, wherein
the gate stack comprises a ferroelectric layer, and
an interface area of the ferroelectric layer includes at least one of TiN, W, Mo, Ru, Pt, or Y.

19. The electronic apparatus of claim 17, wherein
the gate stack comprises a silicon oxide layer, a ferroelectric layer, and a high permittivity layer stacked sequentially on the inner side of the channel hole, and
an interface area of the ferroelectric layer includes at least one of TiN, W, Mo, Ru, Pt, or Y.

20. The electronic apparatus of claim 17, wherein the spacer layer comprises silicon oxide, a metal organic framework, or boron nitride.
